(19) United States
(12) Patent Application Publication
(10) Pub. No.: US 2026/0132991 A1
(43) Pub. Date: May 14, 2026

(54) HEAT DISSIPATION MODULE

(71) Applicant: COOLER MASTER CO., LTD., Taipei City (TW)

(72) Inventors: Pin Chen WANG, Taipei City (TW); Wen-Ching CHEN, Taipei City (TW); Po-Wen TU, Taipei City (TW)

(73) Assignee: COOLER MASTER CO., LTD., Taipei City (TW)

(21) Appl. No.: 19/385,315

(22) Filed: Nov. 11, 2025

(30) Foreign Application Priority Data
Nov. 11, 2024 (TW) 113212259

(51) Int. Cl. F28D 15/02; H05K 7/20

(52) U.S. Cl. CPC F28D 15/0266; H05K 7/20336

(57) ABSTRACT

A heat dissipation module for cooling an optical transceiver module includes a thermal conductive base having a heat dissipation surface and a heat absorption surface, wherein the heat absorption surface is configured to thermally contact the optical transceiver module, and a heat pipe having an evaporation end and a condensation end, the evaporation end disposed on the heat dissipation surface, and the condensation end configured to connect to a heat dissipation device, wherein the heat pipe is configured to contain liquid working fluid and gaseous working fluid, the evaporation end is configured to absorb heat from the thermal conductive base to convert the liquid working fluid into the gaseous working fluid, and the condensation end is configured to cool the gaseous working fluid into the liquid working fluid.

### RELATED APPLICATIONS

This US application claims priority to Taiwan Application No. 113212259, filed on November 11, 2024, of which is incorporated herein by reference in its entirety.

### TECHNICAL FIELD

The present disclosure is related to the field of thermal management systems, in particular to heat dissipation modules having internal flow channels for forming cooling circuits.

### BACKGROUND

Currently, optical fibers are widely employed as the major network transmission medium in many countries throughout the world. Because optical fibers transmit signals via total internal reflection of light, they offer advantages of highspeed transmission and minimal transmission loss. When optical fibers are used as transmission media in network systems, they exhibit broadband, high capacity, and high-speed properties. As the volume of information transmission grows and users expect increasingly high network speeds, the transmission capacity of optical fibers gradually is challenged.

As data transmission demands increase, optical transceiver modules endure heightened workloads, resulting in increased heat dissipation requirements. Optical transceiver modules generate significant heat in high data transmission rate settings, and inadequate heat dissipation may lead to performance deterioration or component failure. Therefore, to maintain stable operation, modern network equipment frequently necessitate advanced heat dissipation technology to address the thermal management needs of these optical transceiver modules.

### SUMMARY

Aspects of the disclosure provide a heat dissipation module for cooling an optical transceiver module. The heat dissipation module can include a thermal conductive base having a heat dissipation surface and a heat absorption surface, wherein the heat absorption surface is configured to thermally contact the optical transceiver module, and a heat pipe having an evaporation end and a condensation end, the evaporation end disposed on the heat dissipation surface, and the condensation end configured to connect to a heat dissipation device, wherein the heat pipe is configured to contain

liquid working fluid and gaseous working fluid, the evaporation end is configured to absorb heat from the thermal conductive base to convert the liquid working fluid into the gaseous working fluid, and the condensation end is configured to cool the gaseous working fluid into the liquid working fluid.

In an embodiment, the evaporation end of the heat pipe thermally contacts the heat dissipation surface of the thermal conductive base. In an embodiment, the heat pipe is a flat heat pipe. In an embodiment, the heat pipe has two opposing wide surfaces, and one of the wide surfaces thermally contacts the heat dissipation surface of the thermal conductive base at the evaporation end.

In an embodiment, a material of the heat pipe can be copper alloy. In an embodiment, a material of the thermal conductive base can be copper alloy.

In an embodiment, the thermal conductive base further has an assembly groove on the heat dissipation surface, and the evaporation end of the heat pipe is disposed in the assembly groove. In some embodiment, the evaporation end can be snugly disposed in the assembly groove.

In an embodiment, a thermal interface material having a high thermal conductivity coefficient can be disposed between the evaporation end and the assembly groove. In an embodiment, the heat dissipation device can include heat dissipation fins, a fan, a liquid cooling radiator, or a thermal conductive plate.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective view of a heat dissipation module and a heat-generating component according to aspects of the present disclosure.

FIG. 2 illustrates a partially exploded view of the heat dissipation module and heat-generating component of FIG. 1.

FIG. 3 illustrates a partially another exploded view of the heat dissipation module and heat-generating component of FIG. 1.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

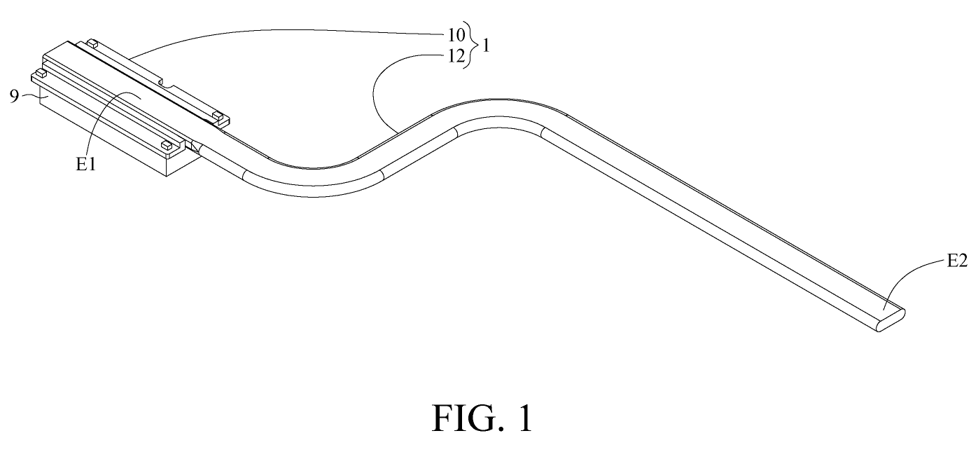

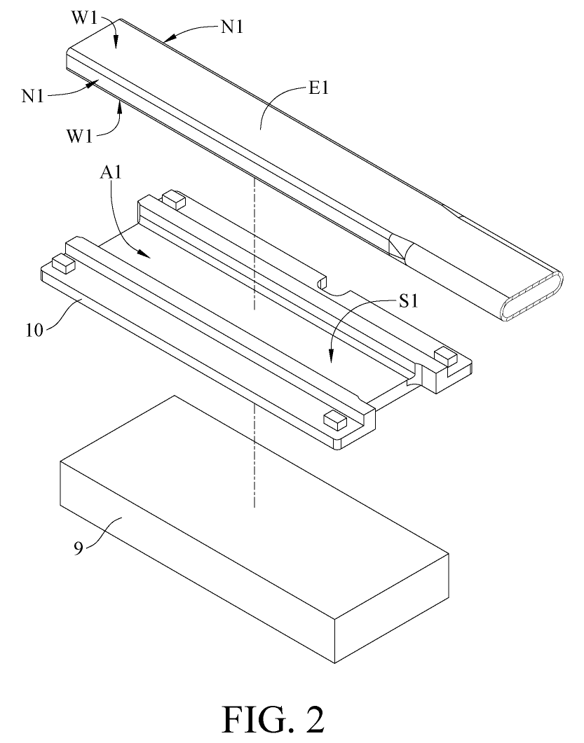

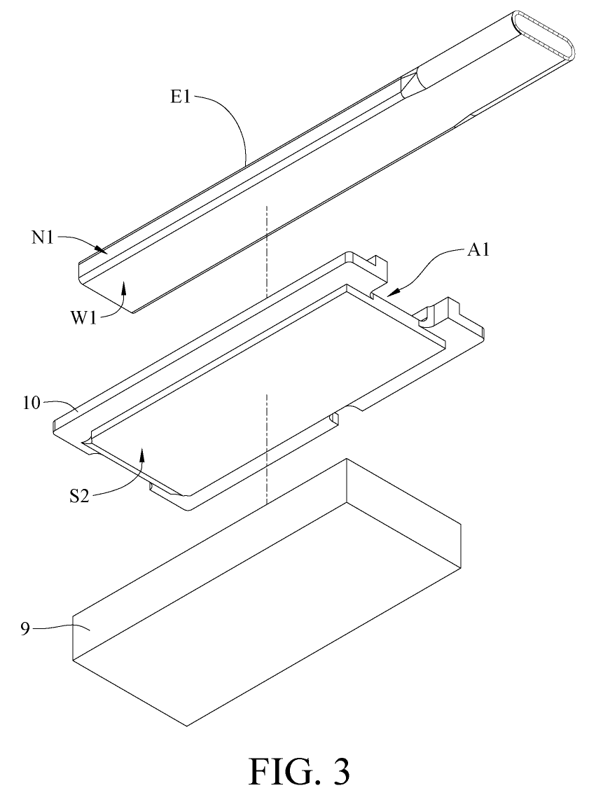

Please refer to FIGS. 1 to 3. FIG. 1 illustrates a perspective view of a heat dissipation module and a heat-generating assembly according to aspects of the present disclosure, FIG. 2 illustrates a partially exploded view of the heat dissipation module and heat-generating assembly of FIG. 1. FIG. 3 is a partially cross-sectional view of the heat dissipation module and heat-generating assembly of FIG. 1. The heat dissipation module 1 of this embodiment is used to cool a heat-generating component 9, which could be a Quad Small Form-factor Pluggable (QSFP) optical transceiver module 9. The structural shape of the heat-generating component is simplified in the drawings. Further, the present disclosure is not limited to the form of the heat-generating component.

The heat dissipation module 1 includes a thermal conductive base 10 and a heat pipe 12. The thermal conductive base 10 includes a heat dissipation surface S1 and a heat absorption surface S2, with the latter arranged to thermally contact the optical transceiver module 9. The thermal conductive base 10 serves as an intermediary thermal conductor, effectively transferring heat from the optical transceiver module 9 to the heat pipe 12. The heat dissipation surface S1 and heat absorption surface S2 are positioned on opposite sides of the thermal conductive base 10, allowing for efficient heat transfer through the base material. The thermal conductive base 10 may be sized and configured to provide an optimal thermal interface with various form factors of optical transceiver modules, including but not limited to QSFP modules.

The heat pipe 12 has an evaporation end E1 and a condensation end E2. The evaporation end E1 is disposed on the heat dissipation surface S1 of the thermal conductive base 10, and the condensation end E2 is configured to connect to a heat dissipation device (not shown). The heat pipe 12 is filled with liquid working fluid that goes through continuous phase transitions to enhance heat transfer. During operation, the evaporation end E1 of the heat pipe 12 absorbs heat from the thermal conductive base 10 and converts the liquid working fluid into gaseous working fluid that diffuses toward the condensation end E2 of the heat pipe 12. At the condensation end E2 of the heat pipe 12, the gaseous working fluid is cooled and condensed, reverting to the liquid working fluid. And, then the liquid working fluid flows back to the evaporation end E1 of the heat pipe 12 via capillary structures (not shown) disposed inside the heat pipe 12 to facilitate continuous two-phase flow heat conduction cycles. The liquid working fluid may include, but is not limited to, water, propane, pentane, or other suitable organic fluids, and it can flow through the heat pipe 12 via gravity, capillary force, or a combination of both. The heat dissipation device may include heat dissipation fins, a fan, a liquid cooling radiator, or a thermal conductive plate.

The heat pipe 12 is a flat heat pipe with two opposing wide surfaces W1, one of which thermally contacts the heat dissipation surface S1 of the thermal conductive base 10 at the end of evaporation end E1. By employing the wide surface W1 of the heat pipe 12 to thermally contact the heat dissipation surface S1 of the thermal conductive base 10, the contact area between the heat pipe 12 and the thermal conductive base 10 can be significantly increased, improving heat transfer efficiency when compared to conventional round heat pipes. The wide surface W1 refers to the two outer surfaces of the heat pipe 12 that the greatest width dimension of any surfaces of the heat pipe 12, and it may be substantially planar to optimize surface contact. The evaporation end E1 may make directly contact with the heat dissipation surface S1, resulting in efficient thermal coupling between the components. The flat configuration of the heat pipe 12 also allows for space-saving installation in compact electronic device housings.

The thermal conductive base 10 may further include an assembly groove A1 on the heat dissipation surface S1, with the evaporation end E1 of the heat pipe 12 disposed in the assembly groove A1, allowing for precise assembly and alignment of the heat pipe 12 and the thermal conductive base 10. In one embodiment, the evaporation end E1 is snugly disposed in the assembly groove A1, allowing both the wide surface W1 of the heat pipe 12 and two narrow surfaces N1 adjacent to the wide surface W1 to physically contact the assembly groove A1 of the thermal conductive base 10. This multi-surface contact configuration enhances the contact area between the heat pipe 12 and the thermal conductive base 10 while maintaining assembly stability and mechanical integrity. The assembly groove A1 serves to ensure a secure fit for the evaporation end E1 while maintaining its optimal thermal interface properties.

In one embodiment, to further improve heat transfer efficiency, a thermal interface material with a high thermal conductivity coefficient (not shown) may be disposed between the evaporation end E1 of the heat pipe 12 and the assembly groove A1 of the thermal conductive base 10. Such thermal interface materials may include, but are not limited to, thermal paste, thermal pads, thermal grease, or other thermally conductive compounds, reducing thermal resistance between interfaces and ensuring more efficient heat transfer from the thermal conductive base 10 to the heat pipe 12. The thermal interface material fills microscopic gaps and surface irregularities between the contacting surfaces, removing air gaps that would otherwise prevent heat transfer. The selection of thermal interface material may depend on aspects such as thermal conductivity, operating temperature range, mechanical properties, and long-term reliability requirements.

In one embodiment, the heat pipe 12 can be made of copper alloy (Cu1100), while the thermal conductive base 10 can also be made of copper alloy, providing excellent thermal conductivity properties suitable for high-performance heat dissipation applications. However, the present disclosure is not limited thereto. In some embodiments, the heat pipe 12 and thermal conductive base 10 may be made of other metallic materials with suitable thermal and mechanical properties, such as aluminum alloy, stainless steel, nickel alloy, titanium alloy, or combinations thereof. The material selection may be optimized according to specific application requirements including thermal performance, weight constraints, corrosion resistance, manufacturing costs, and compatibility with the electronic components being cooled.

According to the heat dissipation module of the previously mentioned embodiment, the phase change characteristics of the liquid working fluid in the heat pipe 12 are utilized to efficiently transfer heat for cooling the optical transceiver module 9, thereby satisfying the demanding heat dissipation requirements of modern high-speed optical transceiver modules. The two-phase heat transfer mechanism provides superior thermal performance compared to conventional single-phase cooling techniques, facilitating efficient cooling of optical transceivers operating at high data transmission rates which cause significant heat generation. This thermal management approach ensures stable operation, prevents performance degradation, and prolongs the operational lifespan of the optical transceiver components.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A heat dissipation module for cooling an optical transceiver module, the heat dissipation module comprising:
a thermal conductive base having a heat dissipation surface and a heat absorption surface, wherein the heat absorption surface is configured to thermally contact the optical transceiver module; and
a heat pipe having an evaporation end and a condensation end, the evaporation end disposed on the heat dissipation surface, and the condensation end configured to connect to a heat dissipation device,
wherein the heat pipe is configured to contain liquid working fluid and gaseous working fluid, the evaporation end is configured to absorb heat from the thermal conductive base to convert the liquid working fluid into the gaseous working fluid, and the condensation end is configured to cool the gaseous working fluid into the liquid working fluid.

2. The heat dissipation module of claim 1, wherein the evaporation end of the heat pipe thermally contacts the heat dissipation surface of the thermal conductive base.

3. The heat dissipation module of claim 1, wherein the heat pipe is a flat heat pipe.

4. The heat dissipation module of claim 3, wherein the heat pipe has two opposing wide surfaces, and one of the wide surfaces thermally contacts the heat dissipation surface of the thermal conductive base at the evaporation end.

5. The heat dissipation module of claim 1, wherein a material of the heat pipe is copper alloy.

6. The heat dissipation module of claim 1, wherein a material of the thermal conductive base is copper alloy.

7. The heat dissipation module of claim 1, wherein the thermal conductive base further has an assembly groove on the heat dissipation surface, and the evaporation end of the heat pipe is disposed in the assembly groove.

8. The heat dissipation module of claim 7, wherein the evaporation end is snugly disposed in the assembly groove.

9. The heat dissipation module of claim 7, wherein a thermal interface material having a high thermal conductivity coefficient is disposed between the evaporation end and the assembly groove.

10. The heat dissipation module of claim 1, wherein the heat dissipation device includes heat dissipation fins, a fan, a liquid cooling radiator, or a thermal conductive plate.
